(19) United States
(12) Patent Application Publication
(10) Pub. No.: US 2018/0090389 A1
(43) Pub. Date: Mar. 29, 2018

(54) INTEGRATED CIRCUIT COMPRISING MOS TRANSISTORS AND METHOD OF MANUFACTURING THE SAME

(71) Applicant: STMicroelectronics (Crolles 2) SAS, Crolles (FR)

(72) Inventors: Guillaume C. Ribes, Bernin (FR); Benjamin Dumont, Saint Martin D'uriage (FR); Franck Arnaud, St. Nazaire Les Eymes (FR)

(73) Assignee: STMicroelectronics (Crolles 2) SAS, Crolles (FR)

(21) Appl. No.: 15/458,109

(22) Filed: Mar. 14, 2017

(30) Foreign Application Priority Data
Sep. 27, 2016 (FR) 1659090

(51) Int. Cl. H01L 21/8238; H01L 27/092; H01L 27/12; H01L 29/78; H01L 29/49; H01L 29/51; H01L 21/84

(52) U.S. Cl. CPC H01L 21/823842; H01L 27/092; H01L 27/1203; H01L 21/84; H01L 29/4966; H01L 29/517; H01L 29/7838

(57) ABSTRACT

An integrated circuit includes FDSOI-type MOS transistors formed inside and on top of a semiconductor layer resting on an insulating layer. The transistors include a logic MOS transistor of a first conductivity type, a logic MOS transistor of a second conductivity type, and an analog MOS transistor of the first conductivity type, A gate stack of the logic transistors successively includes a gate insulator layer, a first titanium nitride layer, a lanthanum layer, and a second titanium nitride layer. A gate stack of the analog transistor includes the gate insulator layer, the lanthanum layer and the second titanium nitride layer but not the first titanium nitride layer.

### PRIORITY CLAIM

This application claims the priority benefit of French Application for Patent No. 1659090, filed on Sep. 27, 2016, the disclosure of which is hereby incorporated by reference in its entirety.

### TECHNICAL FIELD

The present disclosure relates to an integrated circuit comprising MOS transistors and to a method of manufacturing the same. The case where the MOS transistors are of Fully Depleted Semiconductor On Insulator (FDSOI) type is here more particularly considered. Such transistors are formed in a semiconductor layer resting on an insulator and having a thickness smaller than 20 nm, or even smaller than 10 nm.

### BACKGROUND

In an integrated circuit, logic MOS transistors (MOS_{L}) are transistors used to implement logic functions, and analog MOS transistors (MOS_{A}) are transistors used to implement analog functions.

Logic MOS transistors are intended to process digital signals, or logic signals, having a high level and a low level corresponding to the two binary values ‘1’ and ‘0’. Such logic transistors are formed so as to switch rapidly and to consume little electric power. The threshold voltages of logic N-channel MOS transistors, NMOS_{L}, and those of logic P-channel MOS transistors, PMOS_{L}, are generally optimized by providing gate stacks for NMOS_{L} transistors different from those for PMOS_{L} transistors. This implies using many steps of layer masking, deposition, and etching to form these different gate stacks.

The analog transistors are intended to process, for example, to amplify, the analog signals. It is desirable for the analog signals not to be deformed by the analog transistors, and thus for the threshold voltages of the analog transistors to be as low as possible. Due to the fact that the performances of N-channel MOS transistors are better than those of P-channel MOS transistors, the analog functions of an integrated circuit are most often implemented only with analog N-channel MOS transistors, NMOS_{A}. Such analog transistors NMOS_{A} are also formed in the same way as logic transistors NMOS_{L}, which poses various problems, particularly to lower the threshold voltages of NMOS_{A} transistors down to values which are as low as possible.

There is a need in the art for an integrated circuit comprising MOS transistors and a method of manufacturing the same which at least partly overcome some of the disadvantages of existing integrated circuits.

### SUMMARY

An embodiment provides an integrated circuit comprising FDSOI-type MOS transistors comprising at least one logic MOS transistor of a first type, at least one logic MOS transistor of a second type, and at least one analog MOS transistor of the first type, formed inside and on top of a semiconductor layer resting on an insulating layer, wherein: the gate stack of the logic transistors successively comprises a gate insulator layer, a first titanium nitride layer, a lanthanum layer, and a second titanium nitride layer; and the gate stack of the analog transistor comprises the same layers as the gate stack of the logic transistors except for the first titanium nitride layer.

According to an embodiment, the gate insulator layer comprises a layer of high permittivity made of an insulating material having a permittivity greater than 15.

According to an embodiment, said insulating material is selected from the group comprising hafnium oxide, hafnium oxynitride, and zirconium oxide.

According to an embodiment, the thickness of the semiconductor layer is in the range from 5 to 20 nm, preferably from 6 to 13 nm.

According to an embodiment, the gate length of the transistors is smaller than 30 nm.

According to an embodiment, the thickness of the lanthanum layer is in the range from 0.2 to 1 nm, preferably from 0.35 to 0.45 nm.

According to an embodiment, the thickness of the first titanium nitride layer is in the range from 1 to 5 nm, preferably from 2 to 3 nm.

Another embodiment provides a method of manufacturing an integrated circuit comprising logic MOS transistors of a first type and of a second type with an identical gate stack, and at least one analog MOS transistor of the first type, the method comprising, for the forming of the gate stacks of the transistors, successive steps of: a) providing a semiconductor layer resting on an insulating layer; b) forming a gate insulator layer; c) forming a first titanium nitride layer; d) removing by etching the first titanium nitride layer from the location of the analog MOS transistor; e) forming a lanthanum layer; and f) forming a second titanium nitride layer.

According to an embodiment, step b) comprises forming an insulating interface layer on the semiconductor layer followed by the forming of a layer of high permittivity made of a material having a permittivity greater than 15.

According to an embodiment, the thickness of the interface layer is smaller than 2 nm, the thickness of the layer of high permittivity is smaller than 2 nm, the thickness of the first titanium nitride layer is in the range from 1 to 5 nm, preferably from 2 to 3 nm, the thickness of the lanthanum layer is in the range from 0.2 to 1 nm, preferably from 0.35 to 0.45 nm, and the thickness of the second titanium nitride layer is in the range from 1 to 5 nm, preferably from 3.5 to 4.5 nm.

### BRIEF DESCRIPTION OF THE DRAWINGS

The foregoing and other features and advantages will be discussed in detail in the following non-limiting description of specific embodiments in connection with the accompanying drawings, wherein:

FIG. 1 illustrates an embodiment of an integrated circuit comprising MOS transistors; and

FIGS. 2A to 2D illustrate successive steps of an embodiment of a method of manufacturing an integrated circuit of the type in FIG. 1.

### DETAILED DESCRIPTION

The same elements have been designated with the same reference numerals in the various drawings and, further, the various drawings are not to scale. For clarity, only those steps and elements which are useful to the understanding of the described embodiments have been shown and are detailed.

In the following description, terms “rear”, “left”, “right”, “upper”, “lower”, etc. refer to the orientation of the concerned elements in the corresponding drawings. Unless otherwise specified, expression “in the order of” means to within 10%, preferably to within 5%.

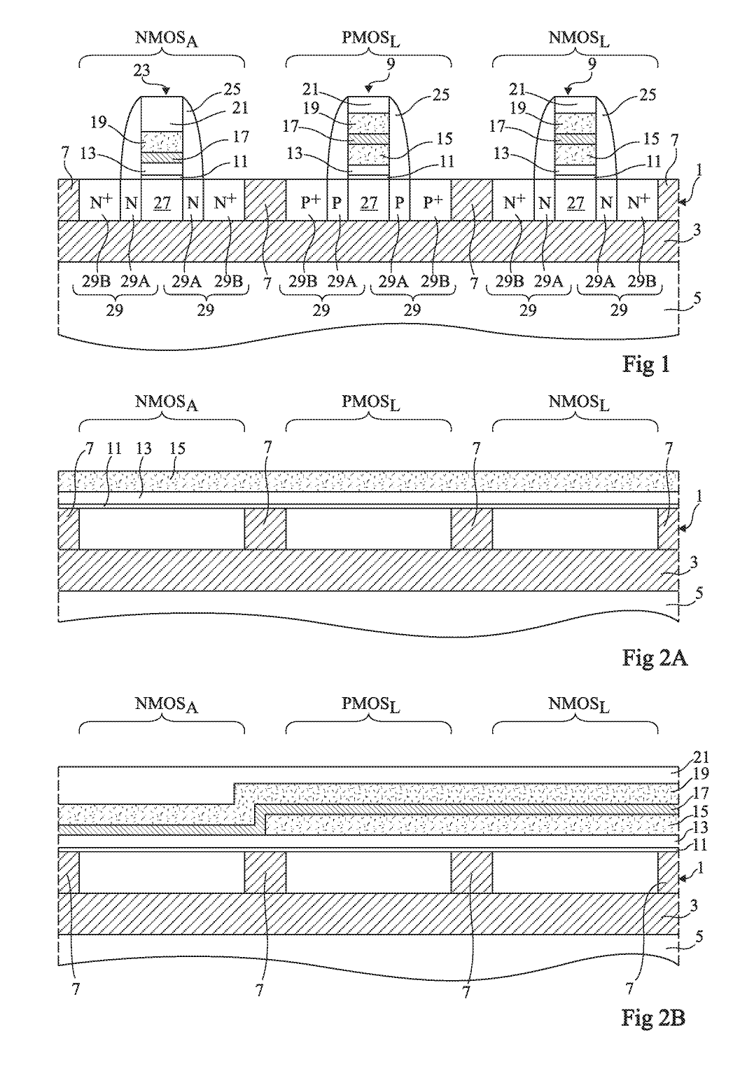

FIG. 1 is a simplified cross-section view schematically illustrating an embodiment of an integrated circuit comprising FDSOI-type MOS transistors. This integrated circuit comprises at least one logic N-channel (N conductivity type) MOS transistor, NMOS_{L}, at least one logic P-channel (P conductivity type) MOS transistor, PMOS_{L}, and at least one analog N-channel (N conductivity type) transistor, NMOS_{A}. A single one of each of the NMOS_{L}, PMOS_{L} and NMOS_{A} transistors is shown, respectively to the right, at the center, and to the left in FIG. 1.

The NMOS_{L}, PMOS_{L} and NMOS_{A} transistors are formed inside and on top of a semiconductor layer 1 resting on an insulator 3, itself resting on a substrate 5. Insulating walls 7 extending through the entire thickness of semiconductor layer 1 delimit each NMOS_{L}, PMOS_{L} and NMOS_{A} transistor and electrically insulate them from other components formed in semiconductor layer 1.

Logic transistors NMOS_{L} and PMOS_{L} have identical gate stacks 9. Each gate stack 9 comprises, on semiconductor layer 1, a gate insulator comprising an insulating interface layer 11 coated with an insulating layer 13 made of a material of high dielectric permittivity. Gate insulator 11, 13 is coated with a conductive gate electrode successively comprising, from layer 13, a titanium nitride layer 15, a lanthanum layer 17, a titanium nitride layer 19, and an upper layer 21, for example, made of doped polysilicon. Layers 11, 13, 15, 17, 19, and 21 rest on one another and are in contact two by two.

Analog transistor NMOS_{A} has a gate stack 23 comprising the same layers as gate stacks 9 of the logic transistors, except for lower titanium nitride layer 15. Thus, in analog transistor NMOS_{A}, lanthanum layer 17 directly rests on insulating layer 13, unlike logic transistors NMOS_{L} and PMOS_{L} where lanthanum layer 17 is separated from insulating layer 13 by titanium nitride layer 15.

In this embodiment, each gate stack 9, 23 is bordered with spacers 25 and rests on an undoped portion 27 of semiconductor layer 1. Portion 27 extends between corresponding source and drain regions 29 formed in semiconductor layer 1 and N-type doped in the NMOS_{A} and NMOS_{L} transistors or of type P in the PMOS_{L} transistors. More particularly, each region 29 comprises a portion 29A arranged under a corresponding spacer 25, and a portion 29B more heavily doped than portion 29A and arranged beyond the gate stack and the spacers. Portions 29A are currently called drain extensions or LDD (lightly doped drain).

According to an advantage, the presence of lanthanum layer 17 directly on gate insulator 11, 13 of analog transistors NMOS_{A} contributes to lowering the threshold voltages of these transistors down to very low values, for example, smaller than 100 mV.

According to another advantage, although the gate stacks of the PMOS_{L} and NMOS_{L} transistors are identical, the layers selected herein to form gate stacks 9 provide optimized threshold voltages for the NMOS_{L} transistors as well as for the PMOS_{L} transistors, for example, threshold voltages smaller than 500 mV. This advantage particularly results from the presence of lower titanium nitride layer 15 interposed between lanthanum layer 17 and insulating layer 13, the thickness of layer 15 being determined by means of simulation software such as the software commercialized under trade names ELDO® or SPECTRE®.

According to another advantage, the gate stacks 9 of the PMOS_{L} transistors comprise no aluminum layer generally used to optimize the threshold voltages of the PMOS_{L} transistors. This results in a decrease in the number of steps necessary to manufacture such gate stacks as compared with the case of gate stacks comprising such an aluminum layer.

Further, the threshold voltages of the NMOS_{L}, PMOS_{L} and NMOS_{A} transistors can be optimized independently from one another, for example, so that the threshold voltages of the NMOS_{L} transistors are equal to those of the PMOS_{L} transistors. To achieve this, the dimensions and/or the doping levels of portions 29A and/or 29B of the source/drain regions 29 of a given transistor type, that is, NMOS_{L} or PMOS_{L} or NMOS_{A}, may be adapted. It may also be provided to apply bias voltages onto rear gate electrodes (not shown) arranged under insulating layer 3, opposite the gate stacks of the transistors. In this last case, advantage is taken from the fact that these transistors are formed inside and on top of a semiconductor layer of Semiconductor On Insulator (SOI) type.

As an example of materials, semiconductor layer 1 may be a silicon, germanium, or silicon-germanium layer. Insulating layer 3 may be made of silicon oxide. Substrate 5 may be made of silicon. Insulating interface layer 11 may be a silicon oxide or silicon oxynitride layer. Insulating layer 13 is a so-called “high-k” material having an electric permittivity greater than 15, for example, hafnium oxide, hafnium oxynitride, or zirconium oxide.

As an example of dimensions, in the case where the gate length of the transistors, taken between drain and source regions 29, is smaller than 30 nm, for example, equal to 28 nm, the various layers may have the following dimensions:
a thickness smaller than 20 nm, preferably in the range from 6 to 13 nm, for example, 6 nm for semiconductor layer 1,
a thickness smaller than 2 nm, for example, 1.5 nm, for interface layer 11,
a thickness smaller than 2 nm, for example, 1.8 nm, for layer 13 of high permittivity,
a thickness in the range from 1 to 5 nm, preferably from 2 to 3 nm, for example, 2.5 nm, for lower titanium nitride layer 15,
a thickness in the range from 0.2 to 1 nm, preferably from 0.35 to 0.45 nm, for example, 0.4 nm, for lanthanum layer 17, and
a thickness in the range from 1 to 5 nm, preferably from 3.5 to 4.5 nm, for example, 4 nm, for upper titanium nitride layer 19.

An integrated circuit of the type in FIG. 1 where the dimensions and the materials of the various layers of the transistors are those indicated hereabove as an example is considered. For a power supply voltage in the order of 1 V, tests have shown that the threshold voltages of analog transistors NMOS_{A}, in linear state, are then only in the order of 55 mV. Further, the tests have shown that the threshold voltages of logic transistors PMOS_{L} and NMOS_{L}, in saturated state, are in the order of −200 mV and of 300 mV, respectively. Thus, the threshold voltages of logic transistors NMOS_{L} are advantageously equal, in absolute value and to within 150 mV, to those of transistors PMOS_{L}. Further, the threshold voltages are advantageously at least twice smaller than the power supply voltage of the integrated circuit.

To manufacture an integrated circuit comprising the NMOS_{L}, PMOS_{L} and NMOS_{A} transistors such as described in relation with FIG. 1, a conventional method would comprise successive steps of uniform deposition of a lanthanum layer 17 on gate insulator 11, 13 of these transistors, and then of removal by etching of lanthanum layer 17 only at the location of logic transistors NMOS_{L} and PMOS_{L}. However, lanthanum etching methods appear to be particularly aggressive and the etching of lanthanum 17 at the location of logic transistors PMOS_{L} and NMOS_{L} would cause an at least partial etching of gate insulator 11, 13 of these transistors. The latter would thus have degraded gate characteristics.

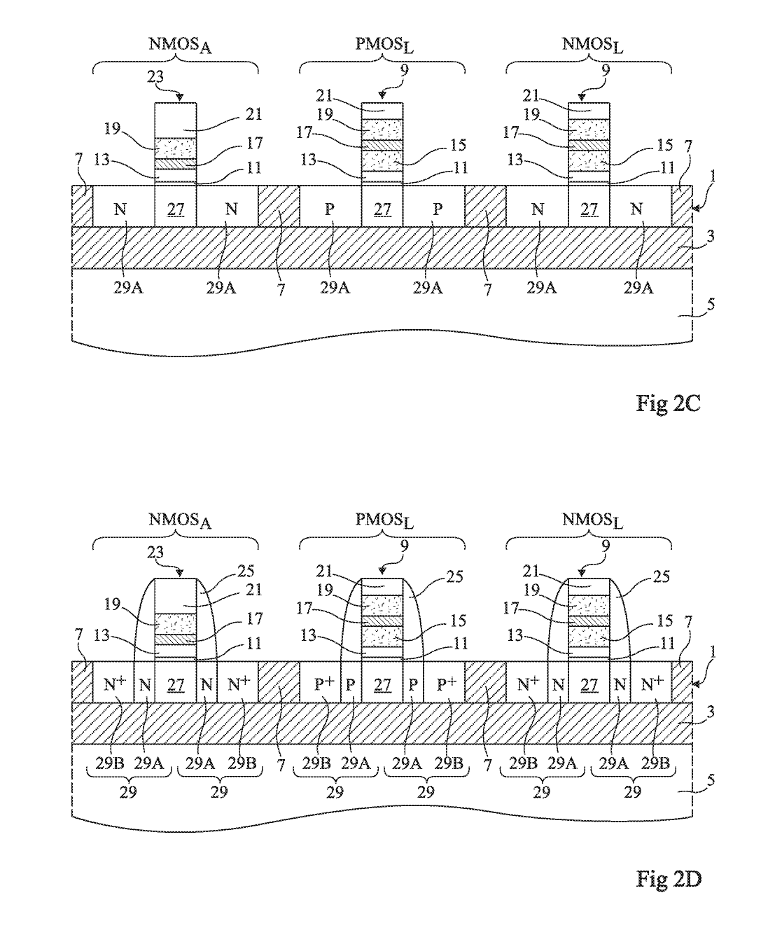

FIGS. 2A to 2D are cross-section views illustrating a structure at successive steps of a manufacturing method avoiding the disadvantages of the conventional method briefly described hereabove. In these drawings, a single NMOS_{A} transistor, a single PMOS_{L} transistor, and a single NMOS_{L} transistor have been shown.

At the step of FIG. 2A, an insulating interface layer 11, an insulating layer of high permittivity 13, and a lower titanium nitride layer 15 have been successively formed at the location of NMOS_{L}, PMOS_{L} and NMOS_{A}, for example all over the surface of semiconductor layer 1 as shown herein.

It should be noted that the first above step is a step of depositing, on gate insulator 11, 13, a layer 15 of titanium nitride rather than lanthanum. Advantageously, selective titanium nitride etching methods are available. It is thus avoided, as will be seen hereafter, to etch lanthanum directly resting on gate insulator 11, 13 at the level of the areas where gate stacks 9 of logic transistors PMOS_{L} and NMOS_{L} are formed.

At the step of FIG. 2B, lower titanium nitride layer 15 has been removed by etching from the location of analog transistor NMOSA and left in place at the location of logic transistors PMOS_{L} and NMOS_{L}. A lanthanum layer 17, an upper titanium nitride layer 19, and a doped polysilicon layer 21 have been successively formed before performing a planarizing polishing of the upper surface of layer 21.

At the step of FIG. 2C, gate stacks 9 and 23 of the NMOS_{L}, PMOS_{L} and NMOS_{A} transistors have been formed by etching, all the way to semiconductor layer 1, layers 11, 13, 15, 17, 19, and 21 to leave in place portions of these layers corresponding to the gate stacks. Source and drain regions 29, and more particularly LDD portions 29A, have then been formed by implantation of dopant atoms, on either side of gate stacks 9, 23.

Advantageously, during the etching of lanthanum layer 17 to define gate stacks 9 and 23 in layers 11, 13, 15, 17, 19, and 21, even if layers 11, 13, and 15 supporting lanthanum 17 are partially etched, this poses no problem since layers 11, 13, and 15 should anyway be removed. Preferably, once lanthanum 17 has been removed by etching, titanium nitride layer 15 is removed by selective etching over gate insulator 11, 13, after which gate insulator 11, 13 is removed by selective etching over semiconductor layer 1, which advantageously enables not to modify the upper surface of layer 1 during the forming of gate stacks 9 and 23.

At the step of FIG. 2D, spacers 25 have been formed on the sides of gate stacks 9, 23, after which new dopant atom implantation steps have been carried out to form heavily-doped portions 29B of source and drain regions 29, portions 29A remaining under spacers 25.

In the above-described method, gate stacks 9, 23 of the NMOS_{L}, PMOS_{L} and NMOS_{A} transistors are formed during the same steps except for the step of etching lower nitride layer 15 specific to the NMOS_{A} transistor. As a result, this method is simpler, faster, and less expensive to implement than existing methods of manufacturing an integrated circuit comprising logic N- and P-channel MOS transistors and for analog N-channel MOS transistors.

Specific embodiments have been described. Various alterations, modifications, and improvements will occur to those skilled in the art. In particular, conductive layer 21 may be formed by means of one or a plurality of conductive layers, for example, layers of conductive materials other than doped polysilicon. In the case where conductive layer 21 is partially or totally made of doped polysilicon, the conductivity type of the polysilicon in the N-channel transistors may be provided to be different from that in P-channel transistors.

Portion 27 of the semiconductor layer may be more lightly N- or P-type doped than regions 29A. For example, it may be provided that at the step of FIG. 2A, the semiconductor layer is lightly N-type or P-type doped.

The spacers bordering gate stacks 9 may be different from those bordering gate stacks 23, particularly as concerns their dimensions, their numbers, and the materials forming them. A plurality of spacers may be provided on either side of gate stacks 9, 23, and the number of these spacers may be different for analog transistors and logic transistors.

Although this is not described, in the manufacturing method illustrated in FIGS. 2A to 2D, after the step of FIG. 2D, steps of siliciding and/or of forming an interconnection structure are currently provided to connect gate stacks 9, 23 and the source/drain regions 29 of the transistors. Steps of epitaxy of source/drain regions 29 may also be implemented.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. An integrated circuit, comprising a plurality of FDSOI-type MOS transistors formed inside and on top of a semiconductor layer resting on an insulating layer, wherein the plurality of FDSOI-type MOS transistors include:
at least one logic MOS transistor of a first conductivity type,
at least one logic MOS transistor of a second conductivity type, and
at least one analog MOS transistor of the first conductivity type,
wherein:
a gate stack of the at least one logic MOS transistor of the first conductivity type and a gate stack of the at least one logic MOS transistor of the second conductivity type each successively comprise a gate insulator layer, a first titanium nitride layer, a lanthanum layer, and a second titanium nitride layer; and
a gate stack of the at least one analog MOS transistor of the first conductivity successively comprises the gate insulator layer, the lanthanum layer, and the second titanium nitride layer but not the first titanium nitride layer.

2. The integrated circuit of claim 1, wherein the gate insulator layer comprises a layer of high permittivity made of an insulating material having a permittivity greater than 15.

3. The integrated circuit of claim 2, wherein said insulating material is selected from the group consisting of: hafnium oxide, hafnium oxynitride, and zirconium oxide.

4. The method of claim 1, wherein a thickness of the semiconductor layer is in a range from 5 to 20 nm.

5. The method of claim 1, wherein a thickness of the semiconductor layer is in a range from 6 to 13 nm.

6. The integrated circuit of claim 1, wherein a gate length of each transistor of the plurality of FDSOI-type MOS transistors is smaller than 30 nm.

7. The integrated circuit of claim 1, wherein a thickness of the lanthanum layer is in a range from 0.2 to 1 nm.

8. The integrated circuit of claim 1, wherein a thickness of the lanthanum layer is in a range from 0.35 to 0.45 nm.

9. The integrated circuit of claim 1, wherein a thickness of the first titanium nitride layer is in a range from 1 to 5 nm.

10. The integrated circuit of claim 1, wherein a thickness of the first titanium nitride layer is in a range from 2 to 3 nm.

11. A method of manufacturing an integrated circuit comprising transistors including logic MOS transistors of a first conductivity type and of a second conductivity type with an identical gate stack and at least one analog MOS transistor of the first conductivity type, the method comprising the step of forming gate stacks of the transistors, wherein forming comprises the successive steps of:
a) forming a gate insulator layer on a semiconductor layer resting on an insulating layer;
b) forming a first titanium nitride layer over the gate insulator layer;
c) removing the first titanium nitride layer from a location of the at least one analog MOS transistor;
d) forming a lanthanum layer on the first titanium nitride layer a locations of the logic MOS transistors and on the gate insulator layer at the location of the at least one analog MOS transistor; and
e) forming a second titanium nitride layer on the lanthanum layer at locations of the logic MOS transistors and the at least one analog MOS transistor.

12. The manufacturing method of claim 11, wherein step a) forming the gate insulator layer comprises forming an insulating interface layer on the semiconductor layer followed by the forming of a layer of high permittivity made of a material having a permittivity greater than 15 on the insulating interface layer.

13. The manufacturing method of claim 12, wherein a thickness of the insulating interface layer is smaller than 2 nm and a thickness of the layer of high permittivity is smaller than 2 nm.

14. The manufacturing method of claim 11, wherein a thickness of the first titanium nitride layer is in a range from 1 to 5 nm, preferably from 2 to 3 nm, a thickness of the lanthanum layer is in a range from 0.2 to 1 nm, preferably from 0.35 to 0.45 nm, and a thickness of the second titanium nitride layer is in a range from 1 to 5 nm, preferably from 3.5 to 4.5 nm.

15. The manufacturing method of claim 14, wherein the thickness of the first titanium nitride layer is in a range from 2 to 3 nm.

16. The manufacturing method of claim 14, wherein the thickness of the lanthanum layer is in a range from 0.35 to 0.45 nm.

17. The manufacturing method of claim 14, wherein the thickness of the second titanium nitride layer is in a range from 3.5 to 4.5 nm.

18. An integrated circuit, comprising a plurality of FDSOI-type MOS transistors formed inside and on top of a semiconductor layer resting on an insulating layer, wherein the plurality of FDSOI-type MOS transistors include:
at least one logic MOS transistor of a first conductivity type,
at least one logic MOS transistor of a second conductivity type, and
at least one analog MOS transistor of the first conductivity type,
wherein:
a gate stack of the at least one logic MOS transistor of the first conductivity type and a gate stack of the at least one logic MOS transistor of the second conductivity type comprises a gate insulator layer, a first titanium nitride layer in contact with the gate insulator layer, a lanthanum layer in contact with the first titanium nitride layer, and a second titanium nitride layer in contact with the lanthanum layer; and
a gate stack of the at least one analog MOS transistor of the first conductivity successively comprises the gate insulator layer, the lanthanum layer in contact with the gate insulator layer, and the second titanium nitride layer in contact with the lanthanum layer.

19. The integrated circuit of claim 18, wherein the gate insulator layer comprises a layer made of a high permittivity insulating material is selected from the group consisting of: hafnium oxide, hafnium oxynitride, and zirconium oxide.

20. The integrated circuit of claim 18, wherein a thickness of the lanthanum layer is in a range from 0.2 to 1 nm.

21. The integrated circuit of claim 18, wherein a thickness of the first titanium nitride layer is in a range from 1 to 5 nm.
